(19) United States
(12) Patent Application Publication
(10) Pub. No.: US 2009/0044063 A1
(43) Pub. Date: Feb. 12, 2009

(54) Semiconductor memory device and test system of a semiconductor memory device

(75) Inventors: Yong-Hwan Cho, Chungcheongnam-do (KR); Byung-Heon Kwak, Gyeonggi-do (KR); Hyun-Soon Jang, Seoul (KR); Jae-Hoon Joo, Gyeonggi-do (KR); Seung-Whan Seo, Chungcheongnam-do (KR); Jong-Hyoung Lim, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/974,342

(22) Filed: Oct. 12, 2007

(30) Foreign Application Priority Data
Oct. 13, 2006 (KR) 10-2006-0099614

(51) Int. Cl. G01R 31/3177; G06F 11/25

(52) U.S. Cl. 714/724; 714/E11.155

(57) ABSTRACT

A semiconductor memory device includes a memory core unit, N data output buffers, N data output ports, and a plurality of test logic circuits. The memory core unit stores test data through N data lines. The N data output buffers are respectively connected to the corresponding N data lines. The N data output ports are connected to the corresponding N data output buffers, and exchange the test data with an external tester respectively. The plurality of test logic circuits receives the test data through the K data lines from the N data lines, performs test logic operation on the received test data, and provides a data output buffer control signal that determines activation of K data output buffers of the N data output buffers in test mode. The semiconductor memory device reduces test cycle.

### CROSS-REFERENCE TO RELATED APPLICATIONS

This application claims priority under 35 USC § 119 to Korean Patent Application No. 10-2006-0099614, filed on Oct. 13, 2006 in the Korean Intellectual Property Office (KIPO), the disclosure of which is incorporated herein in its entirety by reference.

### BACKGROUND OF THE INVENTION

1. Field of the Invention

The present invention relates to a semiconductor memory device, and more particularly to a semiconductor memory device and a method of simultaneously testing a plurality of data output pins.

2. Description of the Related Art

As the integration rate of dynamic random memory access (DRAM) products increases, time and cost of testing the DRAM also increases. A lot of schemes have been developed for reducing the test time and test cost.

The test time can be reduced by a scheme where a plurality of data output pins share one input/output (I/O) channel of a test board.

FIG. 1 is a block diagram illustrating a conventional method where two data output pins share one I/O channel of a test board by data merging.

Referring to FIG. 1, in a conventional method of data merging, pass or fail of merged data 120 is determined based on a voltage level of the merged data 120. Two data output pins DQ0 and DQ8 share one I/O channel of the test board 110. That is, the merged data is determined as pass when the voltage level of the merged data corresponds to logic “high’ level, and the merged data is determined as fail when the voltage level of the merged data corresponds to logic ‘low’ level. When only one of the two data output pins corresponds to pass, the voltage level of the merged data corresponds to logic ‘middle’ level. Therefore, it cannot be determined which data output pin corresponds to fail. In addition, four data output pins cannot be simultaneously tested in the conventional method.

Accordingly, there is a need for a scheme capable of simultaneously testing many data output pins in a reduced time.

### SUMMARY OF THE INVENTION

In accordance with the present invention a semiconductor memory device capable of reducing test cycle and test time can be provided.

Also in accordance with the present invention a test system for a semiconductor memory device capable of reducing test cycle and test time can be provided.

Also in accordance with the present invention a method of testing a semiconductor memory device capable of reducing test cycle and test time can be provided.

In accordance with one aspect of the present invention, a semiconductor memory device includes a memory core unit, N data output buffers, N data output ports, and a plurality of test logic circuits. The memory core unit is configured to store test data through N data lines, where N is a natural number not less than two. The N data output buffers are respectively connected to the corresponding N data lines. The N data output ports are connected to the corresponding N data output buffers, and configured to exchange the test data with an external tester. The plurality of test logic circuits are configured to receive the test data through K data lines from the N data lines, where K is a natural number not less than two and not more than N. The plurality of test logic circuits are also configured to perform test logic operations on the received test data and provide a data output buffer control signal that determines activation of K data output buffers of the N data output buffers in test mode, the K data output buffers corresponding to the K data lines.

The plurality of test logic circuits can be configured to provide the data output buffer control signal having a logic level that is predetermined based on patterns of the test data stored in the memory core unit, and wherein data output buffers corresponding to the test logic circuits that provide logic level different from the predetermined logic level can be deactivated.

Each of the test logic circuits can be configured to receive the test data by the unit of two bits, and the test logic circuits can be configured to simultaneously perform the test logic operation on all the stored test data.

The data output buffer control signal can correspond to a one-bit signal.

Each of the test logic circuits can include an XOR gate when each bit included in the pattern of the test data is identical to one another.

Each of the test logic circuits can include an OR gate when each bit included in the pattern of the test data corresponds to logic ‘zero’.

Each of the test logic circuits can include an AND gate when each bit included in the pattern of the test data corresponds to logic ‘one’.

Each of the test logic circuits can be configured to receive the test data by a unit of four bits, and the test logic circuits can be configured to simultaneously perform the test logic operation on all the stored test data.

The data output buffer control signal can correspond to a one-bit or an N/4-bit signal, and N can be a multiple of four.

When each bit included in the pattern of the test data is identical to one another, the test logic circuit can include a first XOR gate configured to perform an XOR operation of first two bits of the test data, a second XOR gate configured to perform XOR operation of second two bits of the test data, and an OR gate configured to perform an OR operation of outputs of the first and second XOR gates.

When each bit included in the pattern of the test data correspond to logic ‘zero’, the test logic circuit can include a first OR gate configured to perform an OR operation of first two bits of the test data, a second XOR gate configured to perform an OR operation of second two bits of the test data, and a third OR gate configured to perform an OR operation of outputs of the first and second OR gates.

When each bit included in the pattern of the test data corresponds to logic ‘one’, the test logic circuit can include a first AND gate configured to perform an AND operation of first two bits of the test data, a second AND gate configured to perform an AND operation of second two bits of the test data, and an OR gate configured to perform an OR operation of outputs of the first and second AND gates.

In accordance with another aspect of the present invention, a test system of a semiconductor memory device includes a semiconductor memory device configured to store data, a tester configured to test the data stored in the semiconductor memory device, and a test board configured to connects the semiconductor memory device to the tester device through a plurality of input/output (I/O) channels. The semiconductor memory device includes a memory core unit, N data output buffers, N data output pins, and a plurality of test logic circuits, where N is a natural number not less than two. The memory core unit is configured to store test data through N data lines. The N data output buffers are respectively connected to the corresponding N data lines. The N data output pins are connected to the corresponding N data output buffers, and configured to exchange the test data with an external tester respectively. The plurality of test logic circuits are configured to receive the test data through K data lines from the N data lines, where K is a natural number not less than two and not more than N. The plurality of test logic circuits are also configured to perform test logic operations on the received test data and provides a data output buffer control signal that determines activation of K data output buffers of the N data output buffers in test mode, the K data output buffers corresponding to the K data lines. One channel of the plurality of the I/O channels is shared by the data output pins in the same configuration as the test data provided to the test logic circuit are coded.

The plurality of test logic circuits can be configured to provide the data output buffer control signal having a logic level that is predetermined based on patterns of the test data stored in the memory core unit, wherein data output buffers corresponding to the test logic circuits that provide logic level different from the predetermined logic level are deactivated.

Each of the test logic circuits can be configured to receive the test data by a unit of two bits, and the test logic circuits can be configured to simultaneously perform the test logic operation on all the stored test data.

The data output buffer control signal can correspond to a one-bit signal.

Each of the test logic circuits can be configured to receive the test data by a unit of four bits, and the test logic circuits can be configured to perform the test logic operation on all the stored test data simultaneously.

The data output buffer control signal can correspond to a one-bit or an N/4-bit signal, N being a multiple of four.

In accordance with another aspect of the present invention, in a method of testing a semiconductor memory device, test data are stored in a memory core unit through N data lines, where N is an integer not less than two. The test data are received through K data lines from the N data lines, and test logic operation on the received test data, in test mode. Here, K is an integer not less than two and not more than N. Activation of K data output buffers corresponding to the K data lines is determined based on the test logic operation result.

The test logic operation result can have a logic level that is predetermined based on patterns of the test data stored in the memory core unit.

The method can include, when the test logic operation result has a different logic level from the predetermined logic level, deactivating data output buffers corresponding to the different logic level.

The test logic operation can be simultaneously performed on the all the test data, the test data being received by a unit of two bits.

The test logic operation result can correspond to a one-bit signal.

The test logic operation can be simultaneously performed on all the test data, the test data being received by a unit of four bits.

The test logic operation result can correspond to a one-bit or an N/4-bit signal, where N is a multiple of four.

Therefore, the semiconductor memory device, method of testing, and the system of a semiconductor memory device reduce test cycle.

### BRIEF DESCRIPTION OF THE DRAWINGS

FIG. 1 is a block diagram illustrating a conventional semiconductor test method where two data output pins share one I/O channel of a test board by data merging.

FIG. 2 is block diagram illustrating an example embodiment of a semiconductor memory device according to an aspect of the present invention.

FIGS. 3A and 3B are diagrams illustrating example embodiments of the test logic circuit of FIG. 2 when K corresponds to two and four and each bit of test data pattern is lo identical to one another.

FIGS. 4A and 4B are diagrams illustrating example embodiments of the test logic circuit of FIG. 2 when K corresponds to two and four and each bit of test data pattern is logic ‘zero’.

FIGS. 5A and 5B are diagrams illustrating example embodiments of the test logic circuit of FIG. 2 when K corresponds to two and four and each bit of test data pattern is logic ‘one’.

FIG. 6 is a block diagram illustrating an example embodiment of a test system of a semiconductor memory device according to an aspect of the present invention.

FIG. 7A illustrates an example embodiment when one I/O channel of the test board of FIG. 6 is shared by two data output pins.

FIG. 7B illustrates an example embodiment when one I/O channel of the test board of FIG. 6 is shared by four data output pins.

FIGS. 8A and 8B are block diagrams illustrating embodiments of test systems where the test logic circuits in FIGS. 3A and 3B, respectively, are employed in the test board in FIG. 6.

### DESCRIPTION OF THE EMBODIMENTS

Embodiments in accordance with the present invention now will be described more fully with reference to the accompanying drawings. The present invention can, however, be embodied in many different forms and should not be construed as limited to the embodiments set forth herein. Like reference numerals refer to like elements throughout this application.

It will be understood that, although the terms first, second, etc. can be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

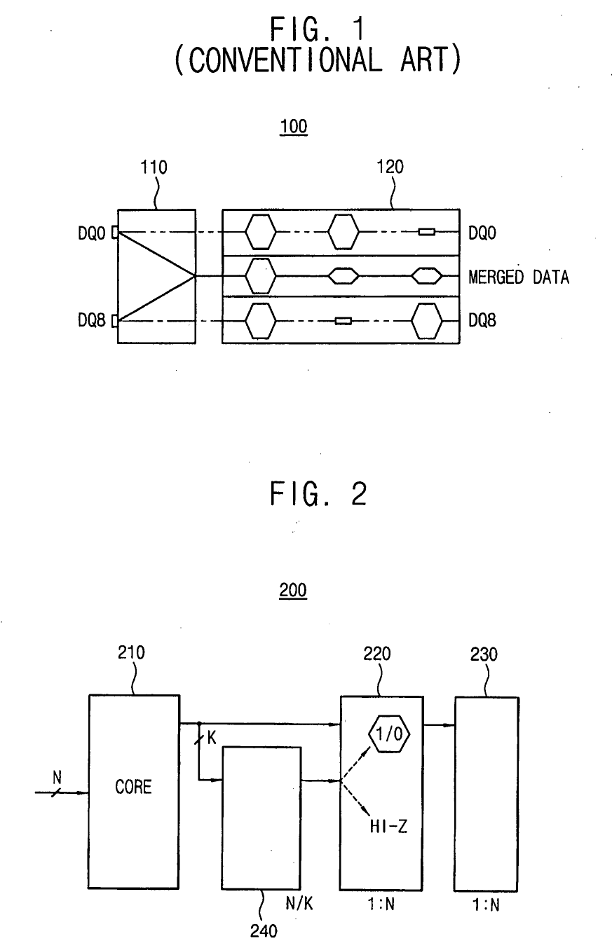

FIG. 2 is block diagram illustrating an example embodiment of a semiconductor memory device according to an aspect of the present invention.

Referring to FIG. 2, a semiconductor memory device 200 includes a memory core unit 210, a data output buffer 220, a data output port 230, and a test logic circuit 240. Even though a single data output buffer 220 and a single data output port 230 are illustrated in FIG. 2, a plural number of the data output buffer 220 and the data output port 230 can be included in the semiconductor memory device 200, wherein the plurality can be represented by N, respectively. Here, N is a natural number not less than two.

The memory core unit 210 stores test data received through N data lines from an external tester (not illustrated). The data output buffer 220 is connected to the corresponding data line, and buffers the test data. The data output port 230 delivers the test data provided from the data output buffer to the external tester and delivers data provided from the external tester to the memory core unit 210.

The test logic circuit 240 receives the test data stored in the memory core unit 210 through K data lines, from among the N data lines, performs test logic operations on the received test data, and provides a data output buffer control signal that determines activation of K data output buffers from among the N data output buffers, in a test mode. Here, the K data output buffers correspond to the K data lines, where K is a natural number not less than two and not more than N.

A number of the test logic circuits 240 included in the semiconductor memory device 200 can correspond to N/K. When K corresponds to two and N corresponds to thirty-two, the number of the test logic circuit 240 can correspond to sixteen, as an example. When K and N respectively correspond to four and thirty-two, the number of the test logic circuit 240 can correspond to eight, as another example.

The test logic circuit 240 provides the data output control signal having a logic level that is predetermined based on patterns of the test data stored in the memory core unit 210. Particular data output buffers 220 corresponding to particular the test logic circuits 240 that provide a logic level different from the predetermined logic level can be deactivated.

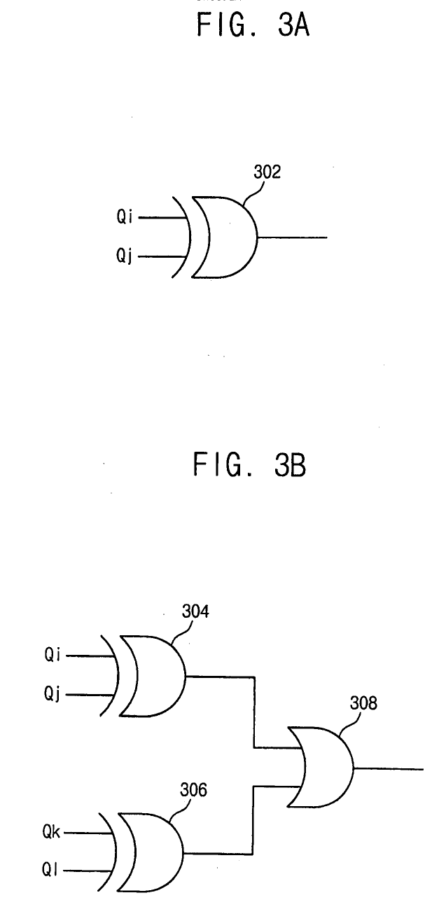

FIGS. 3A through 5B illustrate various example embodiments of the test logic circuit 240 of FIG. 2 for specific illustrative values of K and test data patterns.

FIGS. 3A and 3B are diagrams illustrating example embodiments of the test logic circuit when K corresponds to two and four, respectively, and each bit of test data pattern is identical to one another.

Referring to FIG. 3A, when two bits Qi and Qj of the test data are identical to each other, the test logic circuit 240 can be implemented with an XOR gate 302. When two bits Qi and Qj are different from each other, an output of the XOR gate, that is, a data output buffer control signal, is logic ‘one’. In this case, the data output buffer 220 is provided with the data output buffer control signal that is logic ‘one’, and thus, the data output buffer 220 is deactivated to prevent the data from being provided to the data output port 230. That is, when the data output buffer control signal is logic ‘one’, a state of the data output buffer 220 corresponds to high impedance (Hi-Z) to prevent data from being output.

Referring to FIG. 3B, when four bits Qi, Qj, Qk, and Ql of the test data are identical to one another, the test logic circuit 240 can be implemented with a first XOR gate 304, a second XOR gate 306, and an OR gate 308. The first XOR gate 304 compares first two bits Qi and Qj, and the second XOR gate compares second two bits Qk and Ql. The OR gate 308 receives outputs of the first and second XOR gates 304 and 306. Therefore, when the four bits Qi, Qj, Qk, and Ql are not identical to one another, an output of the OR gate 308, i.e., the data output buffer control signal is logic ‘one’, and thus, the data output buffer 220 is deactivated to prevent the data from being provided to the data output port 230.

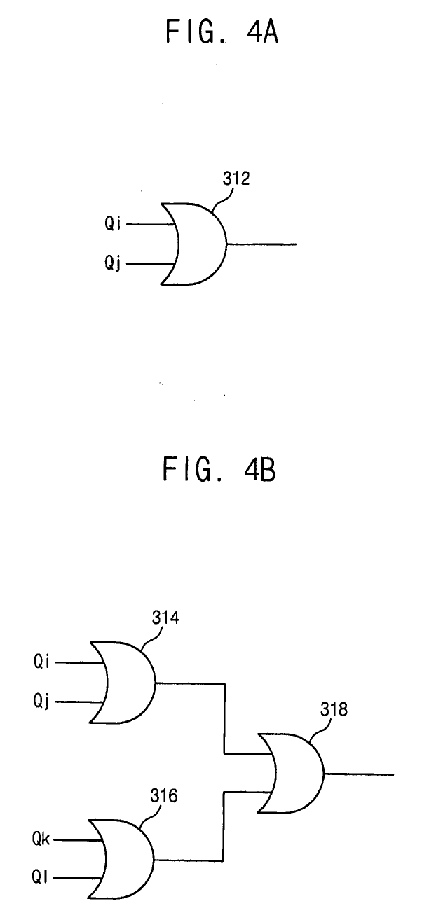

FIGS. 4A and 4B are diagrams illustrating example embodiments of the test logic circuit 240 of FIG. 240 when K corresponds to two and four, respectively, and each bit of test data pattern is logic ‘zero’.

Referring to FIG. 4A, when two bits Qi and Qj of the test data are logic ‘zero’, the test logic circuit 240 can be implemented with an OR gate 312. In this case, when one of the two bits Qi and Qj is not logic ‘zero’, an output of the OR gate 312, i.e., the data output buffer control signal is logic ‘one’, and thus, the data output buffer 220 is deactivated to prevent the data from being output from the data output port 230.

Referring to FIG. 4B, when four bits Qi, Qj, Qk, and Ql of the test data are logic ‘zero’, the test logic circuit 240 can be implemented with a first OR gate 314, a second OR gate 316, and a third OR gate 318. In this case, even when one of the four bits Qi, Qj, Qk, and Ql are not logic ‘zero’, an output of the third OR gate 312, i.e., the data output buffer control signal is logic ‘one’, and thus, the data output buffer 220 is deactivated to prevent the data from being output from the data output port 230.

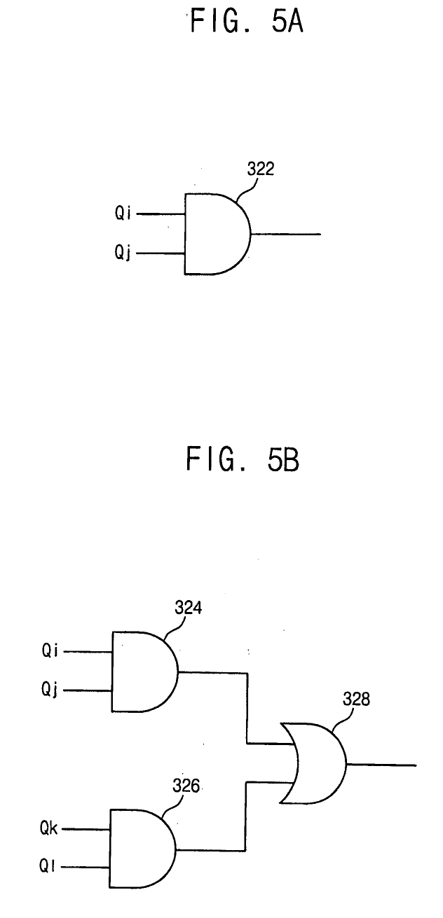

FIGS. 5A and 5B are diagrams illustrating example embodiments of the test logic circuit 240 of FIG. 2 when K corresponds to two and four, respectively, and each bit of test data pattern is logic ‘one’.

Referring to FIG. 5A, when two bits Qi and Qj of the test data are logic ‘one’, the test logic circuit 240 can be implemented with an AND gate 322. In this case, when one of the two bits Qi and Qj is not logic ‘one’, an output of the AND gate 322, i.e., the data output buffer control signal is logic ‘one’, and thus, the data output buffer 220 is deactivated to prevent the data from being provided to the data output port 230.

Referring to FIG. 5B, when four bits Qi, Qj, Qk, and Ql of the test data are logic ‘one’, the test logic circuit 240 can be implemented with a first AND gate 324, a second AND gate 326, and a third AND gate 328. In this case, even when one of the four bits Qi, Qj, Qk, and Ql are not logic ‘one’, an output of the third AND gate 322, i.e., the data output buffer control signal is logic ‘one’, and thus, the data output buffer 220 is deactivated to prevent the data from being provided to the data output port 230.

In FIGS. 3A through 5B, one test logic circuit that is included in the test logic circuit 240 in FIG. 2 is illustrated. When N corresponds to thirty-two and K corresponds to two, sixteen test logic circuits can be included. When N corresponds to thirty-two and K corresponds to four, eight test logic circuits can be included. In addition, when N corresponds to thirty-two and K corresponds to four, the data output buffer control signal is one-bit signal or eight-bit signal. When the data output buffer control signal is one-bit signal, all of the corresponding data output buffers are deactivated. When the data output buffer control signal is eight-bit signal, the data output buffers where fail occur can be selectively deactivated.

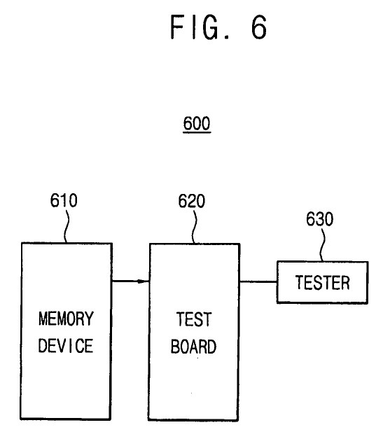

FIG. 6 is a block diagram illustrating an embodiment of a test system of a semiconductor memory device according to an aspect of the present invention.

Referring to FIG. 6, a test system 600 of a semiconductor memory device includes a semiconductor memory device 610, a test board 620, and a tester 630.

The semiconductor memory device 610 stores data, and the tester 630 tests the data stored in the semiconductor memory device 610. The test board 620 connects the semiconductor memory device 610 and the tester 630. The tester 630 provides test data to the semiconductor memory device 610, and receives data from the semiconductor memory device 610 to determine pass or fail of memory cells of the semiconductor memory device 610.

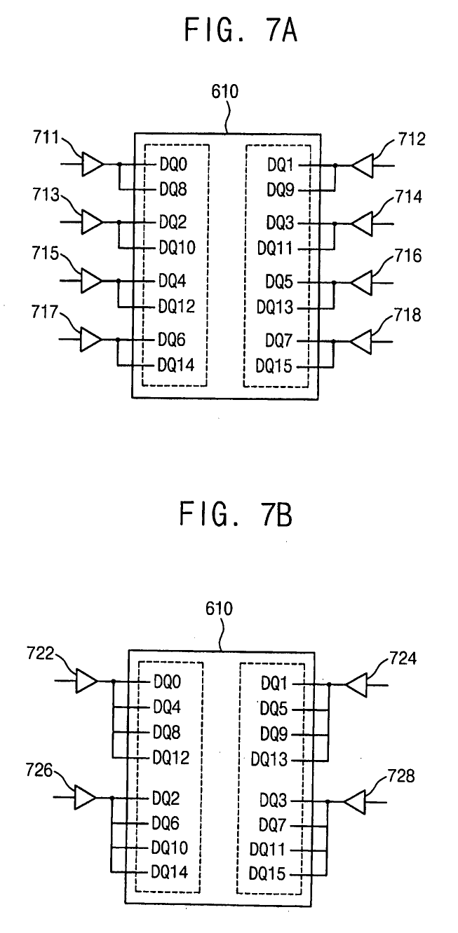

FIG. 7A illustrates an example when one I/O channel of the test board is shared by two data output pins.

Referring to FIG. 7A, when N corresponds to sixteen, each of the I/O channels 711, 712, . . . , 718 of the test board 620 is shared by every two data output pins of the semiconductor memory device 610.

FIG. 7B illustrates an example when one I/O channel of the test board is shared by four data output pins.

Referring to FIG. 7B, when N corresponds to sixteen, each of the I/O channels 722, 724, 726 and 728 of the test board 620 is shared by every four data output pins of the semiconductor memory device 610.

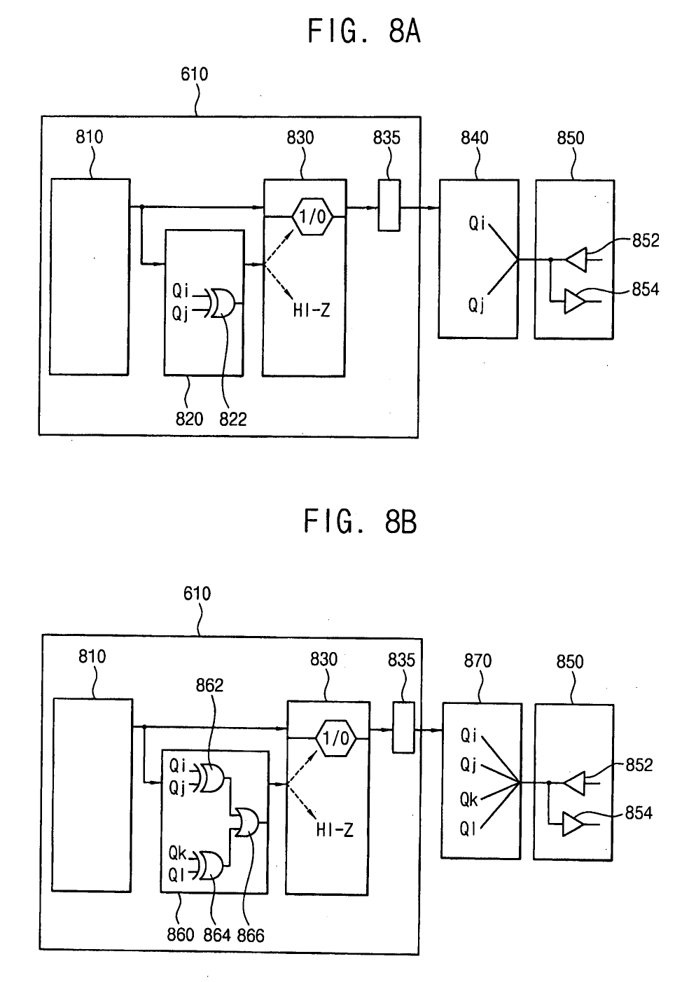

FIGS. 8A and 8B are block diagrams illustrating embodiments of test systems where the test logic circuits in FIGS. 3A and 3B, respectively, are employed in the semiconductor device 610 in FIG. 6, with corresponding embodiments of the test board 620.

Referring to FIG. 8A, in case of K corresponding to two, a test system includes a semiconductor memory device 610, a test board 840, and a tester 850. The semiconductor memory device 610 includes a memory core unit 810, a data output buffer 830, a data output pin 835 and a test logic circuit 820. The data output buffer 830 is connected to the test board 840 through the data output pin 835. The test board 840 connects the semiconductor memory device 610 to the tester 850 through a plurality of I/O channels.

The test logic circuit 820 includes an XOR gate 822 (see also FIG. 3A). When N corresponds to sixteen, a number of the test logic circuit 820 can be eight. One channel of the I/O channel of the test board 840 are shared by two data output pins of the semiconductor memory device 610 in the same configuration as the test data are provided to the test logic circuit 820. The tester 850 includes a data driver 852 and a comparator 854. The tester 850 provides the test data and determines pass or fail of the memory cells of the memory core unit 810, based on data from the test board 840. The test system in FIG. 8A simultaneously tests two memory cells by one read operation.

Referring to FIG. 8B, in case of K corresponding to four, a test system includes a semiconductor memory device 610, a test board 870 and a tester 850. The semiconductor memory device 610 includes a memory core unit 810, a data output buffer 830, a data output pin 835, and a test logic circuit 860. The data output port 830 is connected to the test board 840 through the data output pin 835. The test board 870 connects the semiconductor memory device 610 to the tester 850 through a plurality of I/O channels.

The test logic circuit 860 includes a first XOR gate 862, a second XOR gate 864, and an OR gate 866 (see also FIG. 3B). When N corresponds to sixteen, a number of the test logic circuit 820 can be four. One channel of the I/O channel of the test board 870 are shared by the data output pins of the semiconductor memory device 610 in the same configuration as the test data are provided to the test logic circuit 860. The tester 850 includes a data driver 852, and a comparator 854. The tester 850 provides the test data and determines pass or fail of the memory cells of the memory core unit 810, based on data from the test board 870. The test system in FIG. 8B simultaneously tests four memory cells by one read operation.

In the test systems in FIGS. 8A and 8B, outputs of the test logic circuits 820 and 860, i.e., a data output buffer control signal determines an activation of the corresponding data output buffer 830. When the data output buffer control signal corresponds to logic ‘one’, the corresponding data output buffer 830 is deactivated to prevent data from being output. When the data output buffer control signal corresponds to logic ‘zero’, normal data are output. In addition, the data output buffer control signal can be a one-bit signal or a multi-bit signal.

Hereinafter, referring to FIGS. 2 through 8B, an embodiment of a method of testing a semiconductor memory device according to an aspect of the present invention will be described.

In a method of testing a semiconductor memory device, test data are stored in a memory core unit through N data lines. Here, N is an integer not less than two. The test data are received through N data lines by the unit of K data lines, and a test logic operation is performed on the received test data, in a test mode. Here, K is an integer not less than two and not more than N. Activation of K data output buffers corresponding to the K data lines is determined based on the test logic operation result. The test logic operation result can have a logic level that is predetermined based on patterns of the test data stored in the memory core unit. When the test logic operation result has a different logic level from the predetermined logic level, data output buffers corresponding to the different logic level are deactivated.

As mentioned above, the semiconductor memory device, the test system of a semiconductor memory device, and a method of testing a semiconductor memory device according to aspects of the present invention can reduce a test cycle and obtain exact value of the output data.

While the example embodiments of the present invention and their advantages have been described in detail, it should be understood that various changes, substitutions and alterations can be made herein without departing from the scope of the invention. The invention is, therefore, to be construed as the broadest possible interpretation of the claims and shall not be limited to the specific embodiments provided herein.

What is claimed is:

1. A semiconductor memory device comprising:
a memory core unit configured to store test data through N data lines, where N is a natural number not less than two;
N data output buffers respectively connected to the corresponding N data lines;
N data output ports connected to the corresponding N data output buffers, and configured to exchange the test data with an external tester; and
a plurality of test logic circuits configured to:
receive the test data through K data lines from the N data lines, where K is a natural number not less than two and not more than N
perform test logic operations on the received test data, and
provide a data output buffer control signal that determines activation of K data output buffers of the N data output buffers in a test mode, the K data output buffers corresponding to the K data lines.

2. The semiconductor memory device of claim 1, wherein the plurality of test logic circuits are configured to provide the data output buffer control signal having a logic level that is predetermined based on patterns of the test data stored in the memory core unit, and wherein data output buffers corresponding to the test logic circuits that provide logic level different from the predetermined logic level are deactivated.

3. The semiconductor memory device of claim 2, wherein each of the test logic circuits is configured to receive the test data by the unit of two bits, and the test logic circuits are configured to simultaneously perform the test logic operation on all the stored test data.

4. The semiconductor memory device of claim 3, wherein the data output buffer control signal corresponds to a one-bit signal.

5. The semiconductor memory device of claim 3, wherein each of the test logic circuits includes an XOR gate when each bit included in the pattern of the test data is identical to one another.

6. The semiconductor memory device of claim 3, wherein each of the test logic circuits includes an OR gate when each bit included in the pattern of the test data corresponds to logic ‘zero’.

7. The semiconductor memory device of claim 3, wherein each of the test logic circuits includes an AND gate when each bit included in the pattern of the test data corresponds to logic ‘one’.

8. The semiconductor memory device of claim 2, wherein each of the test logic circuits is configured to receive the test data by a unit of four bits, and the test logic circuits are configured to simultaneously perform the test logic operation on all the stored test data.

9. The semiconductor memory device of claim 8, wherein the data output buffer control signal corresponds to a one-bit or an N/4-bit signal, where N is a multiple of four.

10. The semiconductor memory device of claim 8, wherein when each bit included in the pattern of the test data is identical to one another, each the test logic circuits comprises:
a first XOR gate configured to perform an XOR operation of first two bits of the test data;
a second XOR gate configured to perform XOR operation of second two bits of the test data; and
an OR gate configured to perform an OR operation of outputs of the first and second XOR gates.

11. The semiconductor memory device of claim 8, wherein when each bit included in the pattern of the test data correspond to logic ‘zero’, each of the test logic circuits comprises:
a first OR gate configured to perform an OR operation of first two bits of the test data;
a second XOR gate configured to perform an OR operation of second two bits of the test data; and
a third OR gate configured to perform an OR operation of outputs of the first and second OR gates.

12. The semiconductor memory device of claim 8, wherein when each bit included in the pattern of the test data corresponds to logic ‘one’, each of the test logic circuits comprises:
a first AND gate configured to perform an AND operation of first two bits of the test data;
a second AND gate configured to perform an AND operation of second two bits of the test data; and
an OR gate configured to perform an OR operation of outputs of the first and second AND gates.

13. A test system of a semiconductor memory device, comprising:
a semiconductor memory device configured to store data;
a tester configured to test the data stored in the semiconductor memory device; and
a test board configured to connect the semiconductor memory device to the tester device through a plurality of input/output (I/O) channels,
wherein the semiconductor memory device comprises:
a memory core unit configured to store test data through N data lines, N being a natural number not less than two;
N data output buffers respectively connected to the corresponding N data lines;
N data output pins connected to the corresponding N data output buffers, and configured to exchange the test data with the tester respectively; and
a plurality of test logic circuits configured to:
receive the test data through K data lines from the N data lines, wherein K is a natural number not less than two and not more than N,
perform test logic operations on the received test data, and
provide a data output buffer control signal that determines activation of K data output buffers of the N data output buffers in test mode, the K data output buffers corresponding to the K data lines,
wherein one channel of the plurality of the I/O channels being shared by the data output pins in the same configuration as the test data provided to the test logic circuit are coded.

14. The test system of claim of 13, wherein the plurality of test logic circuits are configured to provide the data output buffer control signal having a logic level that is predetermined based on patterns of the test data stored in the memory core unit, and wherein data output buffers corresponding to the test logic circuits that provide logic level different from the predetermined logic level are deactivated.

15. The test system of claim of 14, wherein each of the test logic circuits is configured to receive the test data by a unit of two bits, and the test logic circuits are configured to simultaneously perform the test logic operation on all the stored test data.

16. The test system of claim of 15, wherein the data output buffer control signal corresponds to one-bit signal.

17. The test system of claim of 14, wherein each of the test logic circuits is configured to receive the test data by a unit of four bits, and the test logic circuits are configured to perform the test logic operation on all the stored test data simultaneously.

18. The test system of claim of 17, wherein the data output buffer control signal corresponds to a one-bit or an N/4-bit signal, N being a multiple of four.

19. A method of testing a semiconductor memory device, the method comprising:
storing test data through N data lines in a memory core unit, N being a natural number not less than two;
receiving the test data through K data lines from the N data lines to perform test logic operation on the received test data in test mode, where K is a natural number not less than two and not more than N; and
determining activation of K data output buffers corresponding to the K data lines based on the test logic operation result, the test data being output through the K data lines.

20. The method of claim 19, wherein the test logic operation result has a logic level that is predetermined based on patterns of the test data stored in the memory core unit.

21. The method of claim 20, wherein the method includes, when the test logic operation result has a different logic level from the predetermined logic level, deactivating data output buffers corresponding to the different logic level.

22. The method of claim 21, wherein the test logic operation is simultaneously performed on the all the test data, the test data being received by a unit of two bits.

23. The method of claim 22, wherein the test logic operation result corresponds to a one-bit signal.

24. The method of claim 21, wherein the test logic operation is simultaneously performed on all the test data, the test data being received by a unit of four bits.

25. The method of claim 24, wherein the test logic operation result corresponds to a one-bit or an N/4-bit signal, where N is a multiple of four.
